(19) United States
(12) Patent Application Publication
(10) Pub. No.: US 2020/0240013 A1
(43) Pub. Date: Jul. 30, 2020

(54) STIRRED BED REACTOR

(71) Applicant: REC Silicon Inc, Moses Lake, WA (US)

(72) Inventor: Robert J. Geertsen, Spokane, WA (US)

(73) Assignee: REC Silicon Inc, Moses Lake, WA (US)

(21) Appl. No.: 16/745,223

(22) Filed: Jan. 16, 2020

Related U.S. Application Data
(60) Provisional application No. 62/796,546, filed on Jan. 24, 2019.
(60) Provisional application No. 62/877,179, filed on Jul. 22, 2019.

(51) Int. Cl. C23C 16/44; B01J 2/00; C01B 33/029; C23C 16/24

(52) U.S. Cl. CPC C23C 16/4417; C23C 16/24; C01B 33/029; B01J 2/006

(57) ABSTRACT

An apparatus for producing particles or material-coated particles by decomposition of precursor gas in a stirred or mixed particle bed comprises a reactor vessel, an actuator assembly comprising a shaft disposed at least partially within the reactor vessel, and an actuator element coupled to the shaft and rotatable therewith. The apparatus further comprises a precursor gas supply in fluid communication with the actuator assembly. The actuator assembly is configured to circulate seed particles of a seed particle bed in the reactor vessel with the actuator element, and to introduce precursor gas from the gas supply to the seed particle bed, when seed particles are received in the reactor vessel.

### CROSS REFERENCE TO RELATED APPLICATION

The present application claims the benefit of U.S. Provisional Application No. 62/796,546, filed Jan. 24, 2019, and U.S. Provisional Application No. 62/877,179, filed Jul. 22, 2019. The entire disclosures of U.S. Provisional Application No. 62/796,546 and U.S. Provisional Application No. 62/877,179 are incorporated herein by reference in their entirety.

### FIELD

The present application relates to decomposition of a precursor gas, such as silicon-bearing gas, in a stirred or mixed particle bed to produced silicon or silicon-coated particles.

### BACKGROUND

Pyrolytic decomposition of silicon-bearing gas in fluidized beds is one process for producing polysilicon for the photovoltaic and semiconductor industries due to excellent mass and heat transfer, increased surface for deposition, and continuous production. Compared with a Siemens-type reactor, the fluidized bed reactor offers considerably higher production rates and reduced energy consumption. The fluidized bed reactor can also be continuous and highly automated to significantly decrease labor costs.

However, a limitation of a fluidized bed reactor is the maximum sized particles that can be practically grown. To maintain fluidization, the minimum gas velocity is exponentially proportional to the particle size. Factors such as compressor size, reactor wall erosion due to higher velocity particle impact, attrition of colliding particles, exhaust filter sizing, fluidization gas heating, etc., limit the amount of gas velocity that can be provided to the bed of particles which establishes the maximum particle size. Fluidized bed reactors also require complex systems to provide the gases necessary to elutriate the particles in the fluidized bed. Accordingly, there exists a need for improved systems for producing polysilicon.

### SUMMARY

Disclosed herein are apparatuses and methods for producing particles or material-coated particles by decomposition of precursor gas in a stirred or mixed particle bed. In a representative embodiment, an apparatus comprises a reactor vessel, an actuator assembly comprising a shaft disposed at least partially within the reactor vessel, and an actuator element coupled to the shaft and rotatable therewith. The apparatus further comprises a precursor gas supply in fluid communication with the actuator assembly. The actuator assembly is configured to circulate seed particles of a seed particle bed in the reactor vessel with the actuator element, and to introduce precursor gas from the gas supply to the seed particle bed, when seed particles are received in the reactor vessel.

In any or all of the described embodiments, the actuator element comprises a blade member extending helically around the shaft.

In any or all of the described embodiments, the actuator element is a first actuator element, the actuator assembly further comprises a second actuator element coupled to the shaft, and the second actuator element comprises an outlet in fluid communication with the precursor gas supply.

In any or all of the described embodiments, the assembly further comprises a non-contact sealing assembly comprising a housing coupled to the reactor vessel and disposed around the shaft to seal an interior of the reactor vessel from the exterior environment, and the precursor gas supply is in fluid communication with the housing of the non-contact sealing assembly.

In any or all of the described embodiments, the shaft comprises an internal conduit in fluid communication with the second actuator element and with the housing of the non-contact sealing assembly, and the internal conduit is configured to conduct precursor gas from the housing to the second actuator element.

In any or all of the described embodiments, the non-contact sealing assembly comprises a first labyrinth seal and a second labyrinth seal spaced apart from each other along the shaft within the housing, the first and second labyrinth seals defining a plenum therebetween.

In any or all of the described embodiments, the plenum is in fluid communication with the internal conduit of the shaft via an opening in the shaft such that precursor gas can flow from the plenum into the internal conduit of the shaft.

In any or all of the described embodiments, the plenum is a first plenum, the internal conduit is a first internal conduit, and the housing further comprises a second plenum in fluid communication with a second internal conduit of the shaft, and with a shield gas source.

In any or all of the described embodiments, the second actuator element comprises an inner conduit and an outer conduit, the outer conduit being coaxially disposed around the inner conduit. The first internal conduit of the shaft is in fluid communication with the inner conduit of the second actuator element, and the second internal conduit of the shaft is in fluid communication with the outer conduit of the second actuator element such that when precursor gas is supplied to the inner conduit and shield gas is supplied to the outer conduit, the shield gas forms a gas envelope around precursor gas exiting the outlet of the second actuator element.

In any or all of the described embodiments, the shaft comprises a first end portion coupled to a driver and a second end portion disposed within the reactor vessel, the first actuator element is coupled to the second end portion of the shaft, and the second actuator element is offset from the first actuator element along the shaft toward the first end portion of the shaft.

In any or all of the described embodiments, the shaft further comprises a coolant conduit in fluid communication with a coolant source.

In any or all of the described embodiments, the shaft is configured as a hollow tube comprising a lumen, the coolant conduit comprises an outlet within the lumen of the shaft, and the assembly further comprises a rotary union coupled to the shaft and in fluid communication with the coolant conduit and with the lumen such that coolant can be introduced to the coolant conduit and withdrawn from the lumen of the shaft.

In any or all of the described embodiments, a method comprises circulating a plurality of seed particles contained in the reactor vessel with the actuator assembly and, with the actuator assembly, introducing a precursor gas comprising a first material into the reactor vessel such that the precursor gas flows through the plurality of seed particles. The method further comprises decomposing the precursor gas such that the first material is deposited on the seed particles to provide product particles, and withdrawing the product particles from the reactor vessel.

In another representative embodiment, a method comprises circulating a plurality of seed particles contained in a reactor vessel with an actuator assembly comprising a shaft and an actuator element coupled to the shaft. The method further comprises, with the actuator assembly, introducing a precursor gas comprising a first material into the reactor vessel such that the precursor gas flows through the plurality of seed particles. The method further comprises decomposing the precursor gas such that the first material is deposited on the seed particles to form product particles, and withdrawing the product particles from the reactor vessel.

In any or all of the described embodiments, the method further comprises introducing the precursor gas further comprises introducing the precursor gas with the actuator element of the actuator assembly.

In any or all of the described embodiments, circulating the seed particles further comprises circulating the seed particles along a path that extends away from the actuator element in a direction along the shaft, radially outwardly away from the shaft, and along walls of the reactor vessel.

In any or all of the described embodiments, decomposing the precursor gas further comprises pyrolizing the precursor gas by application of heat from heat sources external to the reactor vessel.

In any or all of the described embodiments, introducing the precursor gas further comprises supplying the precursor gas to the actuator assembly through a non-contact sealing assembly disposed around the shaft.

In any or all of the described embodiments, the method further comprises supplying a coolant to the actuator assembly, and withdrawing the coolant from the shaft.

In another representative embodiment, an apparatus comprises a reactor vessel, a shaft disposed at least partially within the reactor vessel, a precursor gas supply in fluid communication with the shaft, a first actuator element coupled to the shaft and rotatable therewith, and a second actuator element coupled to the shaft and rotatable therewith, the second actuator element comprising an outlet in fluid communication with the precursor gas supply via the shaft. The first actuator element is configured to circulate seed particles of a seed particle bed in the reactor vessel when seed particles are received in the reactor vessel, and the second actuator element is configured to introduce gas from the precursor gas supply to the seed particle bed.

In another representative embodiment, an apparatus comprises a reactor vessel, and actuator means disposed at least partially within the reactor vessel. The actuator means comprises torque-transmission means and stirring means coupled to the torque-transmission means. The apparatus further comprises a precursor gas supply in fluid communication with the actuator means. The actuator means is configured to stir seed particles of a seed particle bed in the reactor vessel with the stirring means, and to introduce precursor gas from the gas supply to the seed particle bed, when seed particles are received in the reactor vessel.

The foregoing and other objects, features, and advantages of the disclosed embodiments will become more apparent from the following detailed description, which proceeds with reference to the accompanying figures.

### BRIEF DESCRIPTION OF THE DRAWINGS

FIG. 1 is a schematic cross-sectional side view of a representative embodiment of a reactor system.

FIG. 2 is a magnified view of first and second actuator elements coupled to the shaft of the reactor system of FIG. 1.

FIG. 3 is a side elevation view of a representative embodiment of a sealing and gas injection assembly.

FIG. 4 is a cross-sectional view of the sealing and gas injection assembly of FIG. 3.

FIG. 5 is a schematic diagram illustrating the location and direction of movement of a reaction plume within the particle bed of the reactor vessel of FIG. 1.

FIGS. 6 and 7 illustrate additional embodiments of actuator elements that can be used in combination with the reactor system of FIG. 1.

FIG. 8 is a schematic diagram illustrating another embodiment of a reactor system.

FIG. 9 is a cross-sectional view taken along line 9-9 of FIG. 8.

FIG. 10 is a cross-sectional view taken along line 10-10 of FIG. 8.

FIG. 11 is a cross-sectional view of the sealing assembly of FIG. 8.

FIG. 12 is a cross-sectional view taken along line 12-12 of FIG. 8.

FIG. 13 is a cross-sectional view taken along line 13-13 of FIG. 8.

FIG. 14 is a cross-sectional view taken along line 14-14 of FIG. 8.

FIG. 15 is a magnified view of the second end portion of the shaft and the introducer blade member of FIG. 8.

FIG. 16 is a cross-sectional view taken along line 16-16 of FIG. 8.

FIG. 17 is a cross-sectional view of another embodiment of non-contact sealing assembly.

FIG. 18 is a schematic diagram illustrating another embodiment of the reactor system of FIG. 8 including a particle classification system.

### DETAILED DESCRIPTION

The present disclosure concerns embodiments of reactor systems and associated methods for depositing material onto particulate substrates, such as for the formation of granular polysilicon by pyrolytic decomposition of silicon-bearing gas on particles in a stirred, mixed, or circulated bed. Certain embodiments of the reactor system include an actuator assembly including a shaft having one or more actuator elements (e.g., blades) positioned in a bed of seed particles contained in a reactor vessel. Rotation of the shaft and the actuator element(s) can cause the particles to circulate within the bed. A precursor gas containing a material to be deposited on the particles can be supplied from a gas supply to the particle bed through passages in the shaft and in the actuator element(s). The precursor gas can mix with the particles as the particles circulate through the bed. In certain embodiments, the precursor gas can be decomposed, such as by pyrolization, to coat the particles with the selected material. Pyrolization can occur in a plume within the bed. Factors such as the size and shape of the reactor vessel, the particle size, the blade shape, the blade pitch, the blade rotational speed, and/or the flow rate of precursor gas can be selected to control the flow path of particles within the bed and the position of the reaction plume such that material is deposited on the particles, and such that material deposition on surfaces of reactor system components is minimized. The embodiments described herein can reduce or eliminate the need to fluidize the particle bed as is done in traditional fluidized bed reactors. This can improve yield and energy efficiency, and can reduce the complexity of the system as compared to traditional fluidized bed reactors.

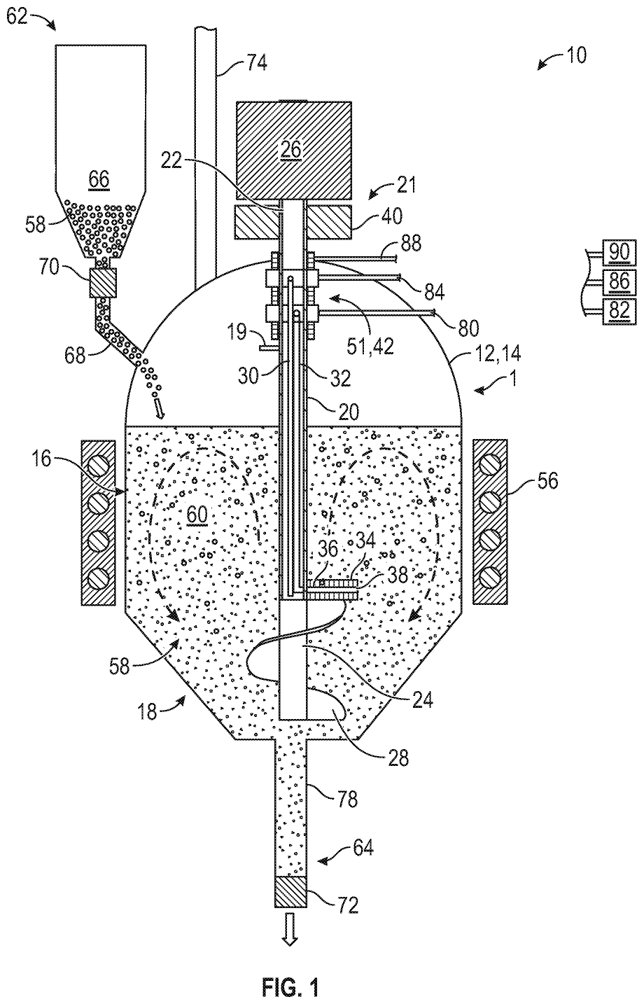

FIG. 1 illustrates a reactor system 10, according to one embodiment. The reactor system 10 can comprise a reactor vessel 12 comprising a first portion 14, a second or intermediate portion 16, and a tapered third or lower portion 18. The reactor vessel 12 can be configured to receive a plurality of granules or particles 58 (also referred to as “seed particles”) which can form a bed 60. An actuator assembly 21 can be positioned at least partially within the reactor vessel 12. More particularly, a shaft 20 of the actuator assembly 21 can extend into the reactor vessel 12, and can comprise a first end portion 22 and a second end portion 24. The first end portion 22 can be coupled to a shaft driver configured as an electric motor 26 located outside the reactor vessel 12 and configured to supply torque to the shaft. The second end portion 24 of the shaft 20 can be offset from the lower surface of the reactor vessel 12, and can comprise one or more actuator elements. For example, in the illustrated configuration, the shaft 20 can comprise actuator elements configured as a first rotor or blade member 28 and a second rotor or blade member 34. Although the shaft 20 is shown centrally aligned with the longitudinal axis of the reactor vessel 12, in other embodiments the shaft 20 may be offset toward one side of the reactor to, for example, promote different mixing characteristics.

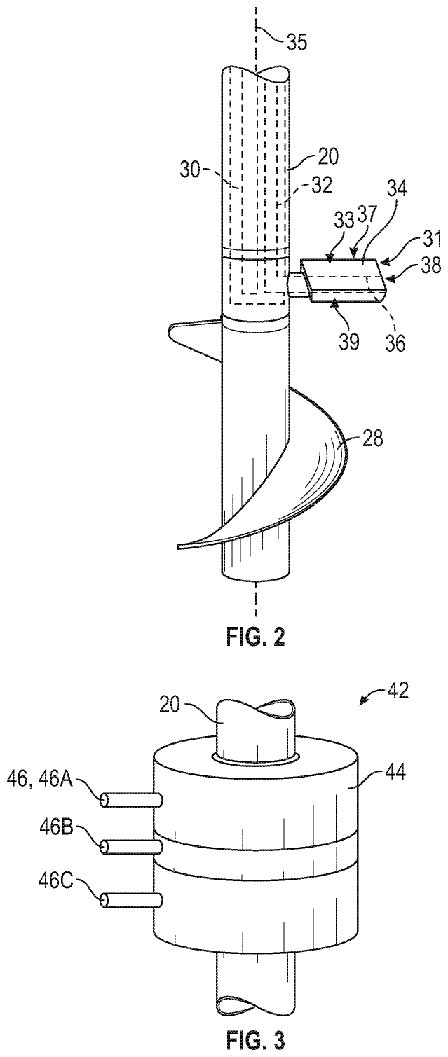

FIG. 2 illustrates the first blade 28 and the second blade 34 in greater detail. The first blade 28 can extend radially outwardly from the shaft 20, and helically along the shaft in the manner of an auger. In the illustrated configuration, the first blade 28 extends 360° around the shaft 20, but may extend any angular distance around the shaft and may have any selected pitch. Certain embodiments can also include two or more entwined helical blades coupled to the shaft 20. The second blade 34 can be offset from the first blade 28 along the shaft 20 in the direction of the first portion 14 of the reactor vessel 12. In the illustrated embodiment, the second blade member 34 comprises a member having flat surfaces 33 oriented at an angle with respect to the direction of rotation of the shaft 20. For example, in the illustrated configuration the second blade 34 is inclined 45° relative to the axis 35 of the shaft 20. However, the second blade 34 can be oriented at any angle to the shaft, and may also comprise a curved shape in the manner of an airfoil depending upon the particular requirements of the system. In some embodiments, the second blade 34 can be configured to allow variation of the angle or pitch of the blade during operation. In some embodiments, the first blade 28 can be configured as a series of smaller blades arranged helically around the shaft 20. The blades can also be arranged in groupings or stages spaced apart longitudinally along the shaft 20. In certain embodiments, the first blade 28 and/or the second blade 34 can be coupled to the shaft by welding followed by a plasma coating of SiC, and/or by a threaded coupling.

Returning to FIG. 1, the shaft 20 can comprise one or more conduits for conducting fluids along its length. For example, in the illustrated embodiment the shaft 20 can be a hollow tube, and can comprise a first conduit 30 and a second conduit 32 for conducting one or more of a cooling fluid (e.g., a gas or liquid) and/or a precursor gas (e.g., a silicon-bearing gas), as further described below. In the illustrated embodiment, the second blade member 34 can be configured as a precursor gas injector, and the conduit 32 can be in fluid communication with the interior of the reactor vessel via a conduit 36 and an outlet 38 defined in the second blade 34. Referring to FIG. 2, in certain embodiments, the outlet 38 can be located at the radially outward edge 31 of the second blade 34. In other embodiments, the outlet 38 may be located at the trailing edge 37. In yet other embodiments, the second blade 34 may include outlets at any of the leading edge 39, the radially outward edge 31, the angled surface(s) 33, the trailing edge of the blade 34, or combinations thereof.

Referring again to FIG. 1, the system 10 can comprise a gas injection system generally indicated at 51. The gas injection system 51 can provide fluid delivery to the conduits 30 and 32 within the shaft from sources external to the reactor 12. For example, a conduit 80 can couple the conduit 32 with a precursor gas supply or source 82 external to the reactor vessel 12. Likewise, a conduit 84 can couple the conduit 30 to a cooling liquid or gas supply or source 86. The gas injection system 51 can comprise a non-contact sealing assembly 42 disposed around the shaft 20 and further described below. A conduit 88 can couple a sealing gas supply or source 90 to the sealing assembly 42. In yet other embodiments, the first blade 28 can comprise one or more channels in fluid communication with the conduit 32 and an outlet (e.g., along the radially outward edge and/or along the trailing edge of the blade) through which precursor gas can be introduced into the seed particle bed in place of, or in addition to, the outlet 38 of the second blade 34. Such an outlet can be configured, for example, as a series of openings along the outer edge and/or the trailing edge of the first blade 28, or as a continuous opening in the outer edge and/or the trailing edge of the blade that extends along at least a portion of the respective edge.

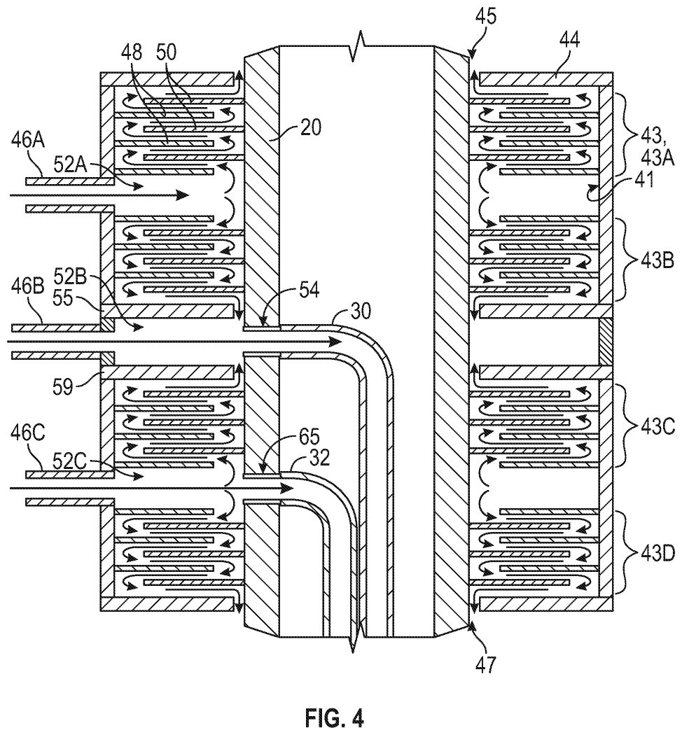

The shaft 20 can be supported above the reactor vessel by a bearing 40. The non-contact sealing assembly 42 can be disposed around the shaft 20 where the shaft extends into the reactor vessel 12. FIGS. 3 and 4 illustrate the sealing assembly 42 in greater detail. The sealing assembly 42 can comprise a housing 44 including a plurality of inlet fittings 46. For example, in the illustrated embodiment the housing 44 can comprise a first inlet fitting 46A, a second inlet fitting 46B, and a third inlet fitting 46C. With reference to FIG. 4, each of the inlet fittings 46A-46C can be in fluid communication with the interior of the housing 44. The housing 44 and the shaft 20 can be separated by an opening or gap 45 where the shaft enters the housing, and by a gap 47 where the shaft exits the housing such that the shaft extends through, but does not contact, the housing.

The housing 44 can comprise a plurality of baffle members 48 extending radially inwardly from the interior surface 41 of the housing. The shaft 20 can comprise a plurality of corresponding baffle members 50 extending radially outwardly and overlapping with, but not contacting, the baffle members 48. Thus, the baffles 48 and the baffles 50 can be arranged alternatingly along the axis of the shaft 20. When the shaft 20 rotates, the baffles 50 can rotate within the housing 44 relative to the baffles 48, and without contacting the baffles 48 or the housing 44.

In the illustrated embodiment, the baffles 48 and the baffles 50 can be arranged in groups or sets to form non-contact sealing arrangements configured as labyrinth seals 43 in which the rotating and stationary elements form a seal without making physical contact with each other. The baffles 48 and 50 of each labyrinth seal 43 can define a tortuous path to at least partially seal different portions of the housing 44 from each other, and to at least partially seal the interior of the housing from the ambient, and from the inside of the reactor. For example, the labyrinth seals 43 can be axially offset from each other along the length of the shaft such that the housing 44 defines a chamber or plenum at the location of each of the inlet fittings 46A-46C. In the illustrated configuration, the housing 44 can define a plenum 52A in fluid communication with the first inlet 46A, a plenum 52B in fluid communication with the second inlet 46B, and a plenum 52C in fluid communication with the fitting 46C. Each of the plenums 52A-52C can have a labyrinth seal 43 located above and below it. More particularly, a labyrinth seal 43A can be disposed above the plenum 52A, and a labyrinth seal 43B can be disposed below the plenum 52A. The plenum 52B can be located between the labyrinth seal 43B and a labyrinth seal 43C, and the plenum 52C can be located between the labyrinth seal 43C and a labyrinth seal 43D. In this manner, the labyrinth seals 43 can: (1) at least partially isolate the plenum 52B from the plenums 52A and 52C; (2) at least partially isolate the plenum 52B from the exterior of the reactor vessel; and (3) at least partially isolate the plenum 52C from the interior of the reactor vessel.

Still referring to FIG. 4, a member 55 can extend inwardly from the housing 44 toward the shaft 20, and can define an upper boundary of the chamber 52B. The member 55 can also define the final segment of the flow path through the labyrinth seal 43B. The housing can also comprise a member 59 extending inwardly from the housing 44 and forming the lower boundary of the chamber 52B. The member 59 can also define the final segment of the flow path through the labyrinth seal 43C. The shaft 20 can comprise an opening 54 located between the members 55 and the member 59. The opening 54 can place the internal conduit 30 of the shaft 20 in fluid communication with the plenum 52B. Thus, liquid or gas introduced to the plenum 52B from the inlet 46B, and any gas that passes through the labyrinth seals above and below the plenum 52B, can flow into the shaft 20 through the opening 54, as described in greater detail below. An opening 65 in the shaft can couple the conduit 32 in fluid communication with the plenum 52C such that liquid or gas introduced into the plenum 52C from the inlet 46C can flow into the conduit 32. In certain embodiments, members 55 and 59 can be disks situated in the housing.

In the illustrated configuration, the sealing assembly 42 can be partially disposed within the reactor vessel 12 such that a portion of the housing 44 is located inside the reactor vessel and a portion of the housing is located outside the reactor vessel, although in other embodiments the housing 44 may be wholly inside or wholly outside the reactor vessel depending upon the particular requirements of the system.

In other configurations, the labyrinth seals 43 can include a single set of baffles, such as either the baffles 48 or the baffles 50. For example, the baffles 48 can be configured to extend across the interior of the housing 44 such that there is a very small clearance or gap between the baffles 48 and the shaft to create a labyrinth seal. Similarly, the baffles 50 can be configured to extend from the shaft 20 across the interior of the housing 44 such that there is a very small clearance or gap between the baffles 50 and the interior wall of the housing. Such labyrinth seals can include any selected number of baffles. In yet other embodiments, sealing between the housing 44 and the shaft 20 can be effected by other types of non-contact seals, such as gap seals. Depending upon purity requirements and seal performance, various other types of sealing arrangements that contact the shaft 20 can also be used, such as face seals, compression packings, O-rings, etc.

Returning to FIG. 1, the reactor system 10 can also comprise one or more heat sources 56 disposed around the intermediate portion 16 of the reactor vessel. In certain embodiments, the heat sources 56 can be configured as electric resistance heaters, electric induction heaters, or any other conductive or radiant heat source.

The system 10 can also comprise a particle source generally indicated at 62, and a particle withdrawal system generally indicated at 64. The particle source 62 can comprise a vessel or hopper 66 that can be filled with particles 58 (e.g., of the type in the bed 60). The hopper 66 can be in communication with the reactor vessel 12 via a conduit 68. A flow control device such as a valve 70 can control flow of particles 58 from the hopper 66 into the reactor vessel 12. The particle withdrawal system 64 can comprise a conduit 78 in fluid communication with the lower portion 18 of the reactor vessel 12. A flow control device such as a valve 72 can control the flow of particles 58 out of the reactor vessel. In certain embodiments, the particle withdrawal system can also include a degasser (e.g., to remove process gasses from the particle stream), and/or a gas classifier to sort particles based on their size. In some embodiments, particles below a predetermined size can be returned to the hopper 66 for further processing in the reactor vessel.

The system 10 can also include a gas filter and/or recycle conduit 74, through which gaseous reaction products (e.g., hydrogen gas) can be withdrawn from the reactor vessel 12.

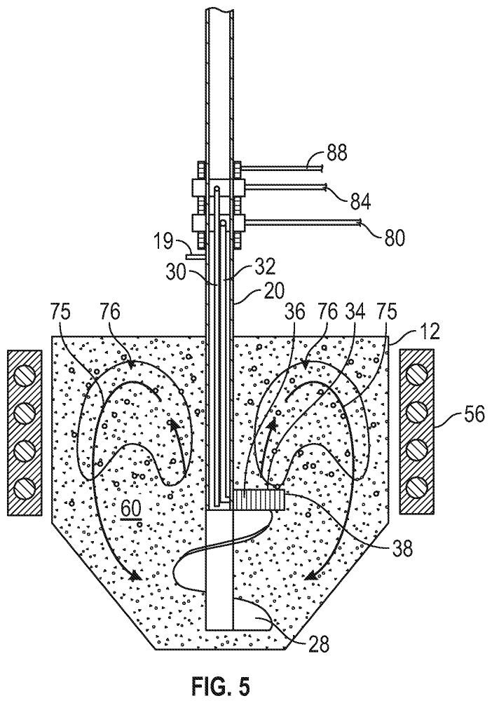

Referring to FIGS. 1 and 5, in operation the reactor vessel 12 can be filled or charged with particles 58, the heat sources 56 can be activated to pre-heat the particles, and the shaft 20 can be rotated by the motor 26 to mix, stir, or circulate the particle bed around the reactor vessel 12. For example, in certain embodiments the first blade 28 can mix or circulate the particles 58 in a toroidal path 75 upwardly along the shaft 20 (e.g., through the reactive gas plume), radially outwardly toward the side walls of the reactor vessel 12 (e.g., through a heating zone), and downwardly along the side walls toward the actuator, although other paths are possible. The toroidal path 75 can also rotate about the axis of the shaft 20 as the blades mix the bulk material, resulting in a swirling toroid. In certain embodiments, the blades can circulate the particles 58 in the bed 60 without elutriating or fluidizing the particles. In certain embodiments, the second blade 34 can lift, separate, agitate or break up the surface layer of the bed 60 to improve mixing throughout the depth of the bed and reduce the bulk density of the material. In certain embodiments, the second blade 34 can induce oscillatory upward and downward motion of particles in the portion of the bed 60 above the second blade. In certain embodiments, the second blade 34 can lift a bulk of the seed particle bed in an oscillating manner to generate a rotating wave. As the rotating blade lifts the portion of the bed that is above the rotating blade 34, the particles can rise, reach a peak height, and fall back into the bed. The expansion of the bed or separation of the bed particles creates more space between particles, which can reduce the pressure, reduce inter-particle friction, and result in higher velocity circulation. This can allow the depth of the bed to be increased while reducing grinding of the particles by the blades, which might otherwise occur due to lower particle mobility.

Precursor gas comprising a material to be deposited on the particles 58 can be supplied to the outlet 38 of the second blade 34 via the sealing assembly 42 and the conduit 32. More particularly, with reference to FIGS. 1 and 4, sealing gas (e.g., hydrogen gas) can be supplied to the sealing assembly 42 from the gas source 90, and introduced into the chamber 52A via the inlet 46A. The sealing gas can be at a pressure greater than the ambient pressure such that a portion of the sealing gas flows through the labyrinth seal 43A and exits the housing 44 via the gap 45 to seal the housing from the ambient. The remainder of the sealing gas can flow through the labyrinth seal 43B into the chamber 52B, where it can mix with cooling gas and/or precursor gas supplied from the precursor gas source 82.

Cooling gas can be supplied from the cooling gas source 86 to the plenum 52B via the conduit 84. The cooling gas can enter the conduit 30 through the opening 54 in the shaft 20, and can be conducted along the length of the shaft to cool the shaft and the attached components. In this manner, the sealing assembly 42 can perform as a rotary union for delivering fluids to the interior of the rotating shaft 20. In some embodiments, heated cooling gas can be withdrawn from the first end portion 22 of the shaft 20 (e.g., by flowing the gas along the conduit 30, along a separate conduit, or along the inside lumen of the shaft), and/or the cooling gas can be vented into the particle bed 60. In some embodiments, cooling gas can be vented from the shaft into the reactor vessel 12 through a vent port 19 (FIG. 1). In the illustrated embodiment, the conduit 30 is shown extending to the level of the second blade member 34. However, in other embodiments, the conduit 30 can extend to the lower end of the shaft, or along any portion of the shaft, depending upon the particular requirements of the system.

Precursor gas can be supplied from the precursor gas source 82 to the plenum 52C via the conduit 80. The precursor gas can enter the conduit 32 through the opening 65 in the shaft 20, and can be conducted along the length of the shaft to the conduit 36 of the second blade member 34. The precursor gas can then be injected into the bed 60 from the outlet 38 as the blade 34 is rotated.

With reference to FIG. 5, the precursor gas can undergo pyrolysis in a reaction plume generally indicated at 76 within the particulate bed 60, and can coat the particles 58 with the product released by the pyrolysis reaction. Due to the motion of the particles 58 upward and outward toward the walls of the reactor vessel, the pyrolysis reaction can take place away from the blades 28 and 34, and away from the shaft 20, reducing material deposition on those components. The reaction plume 76 can also be spaced radially inward from the walls of the reactor vessel 12, reducing unwanted material deposition on the interior of the reactor vessel.

Particles 58 coated with the product (also referred to as “product particles”) can be withdrawn from the reactor vessel 12 through the conduit 78, and fresh particles can be added to the reactor vessel from the particle source 62 to maintain the particle bed 60 at a selected height, either continuously or in batches.

In some embodiments, the particles 58 can comprise polysilicon particles, and the precursor gas can comprise a silicon-bearing gas. Silicon can be deposited on the particles in the reactor by decomposition of a silicon-bearing gas, such as silane (SiH₄), disilane (Si₂H₆), higher order silanes (SiₙH₂ₙ₊₂), dichlorosilane (SiH₂Cl₂), trichlorosilane (SiHCl₃), silicon tetrachloride (SiCl₄), dibromosilane (SiH₂Br₂), tribromosilane (SiHBr₃), silicon tetrabromide (SiBr₄), diiodosilane (SiH₂I₂), triiodosilane (SiHI₃), silicon tetraiodide (SiI₄), and mixtures thereof. The silicon-bearing gas may be mixed with one or more halogen-containing gases, defined as any of the group comprising, consisting essentially of, or consisting of chlorine (Cl₂), hydrogen chloride (HCl), bromine (Br₂), hydrogen bromide (HBr), iodine (I₂), hydrogen iodide (HI), and mixtures thereof. The silicon-bearing gas may also be mixed with one or more other gases, including hydrogen (H₂) or one or more inert gases selected from nitrogen (N₂), helium (He), argon (Ar), and neon (Ne). In particular embodiments, the silicon-bearing gas is silane, and the silane is mixed with hydrogen.

In certain embodiments, precursor gas-wetted surfaces such as the reactor vessel 12, the shaft 20, one or both of the blades 28 and 34, etc., can be made from or coated with silicon, silicon carbide, quartz, etc. In the case of polysilicon production, this can reduce the introduction of impurities into granules from components of the system, resulting in a higher purity product.

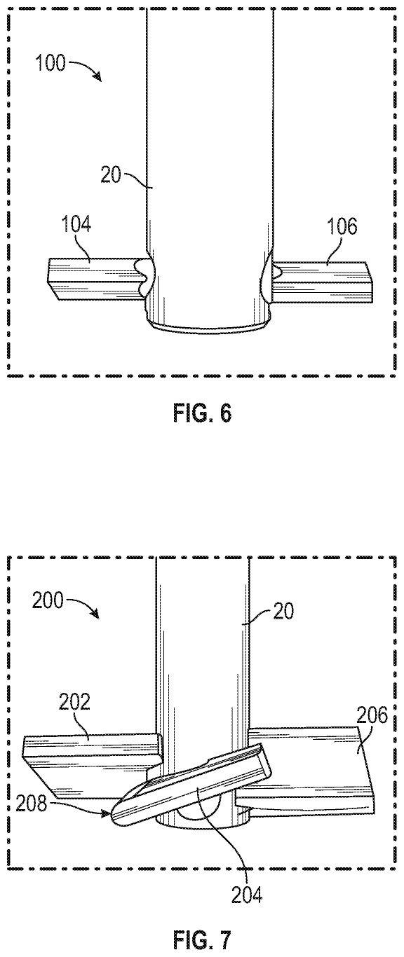

FIGS. 6 and 7 illustrate other embodiments of actuator elements that may be used in combination with the actuator assembly 21. FIG. 6 illustrates an actuator element 100 coupled the shaft 20. Two blade members 104 and 106 extend radially outwardly from opposite sides of the shaft 20. The blade members 104 and 106 can be angled with respect to the direction of rotation of the shaft 20 in a manner configured to direct material upwardly along the shaft, and can be curved or flat. In certain embodiments, the angle of the blade members 104 and 106 can be varied, either together or independently. In certain embodiments, one or both of the blade members 104 and 106 can comprise passages and/or outlets in fluid communication with the interior of the shaft 20 to conduct precursor gas and/or cooling gas and introduce such gases into the particle bed.

FIG. 7 illustrates another embodiment of an actuator element 200 comprising four blade members coupled to the shaft 20, of which only three blades 202, 204, and 206 are visible in FIG. 7. The blades can be angled with respect to the shaft, and the angle of the blades can be adjustable during operation. As best shown with reference to the blade 202, at least the leading edges 208 of the blades can be rounded to facilitate movement of the blades through the particles in the bed 60. The blades may also comprise passages and outlets in fluid communication with the interior of the shaft 20 to introduce precursor gas into the particle bed. Any of the actuator elements 100 and/or 200 may be used in combination with, or in place of, one or more of the first blade member 28 and/or the second blade member 34 described above.

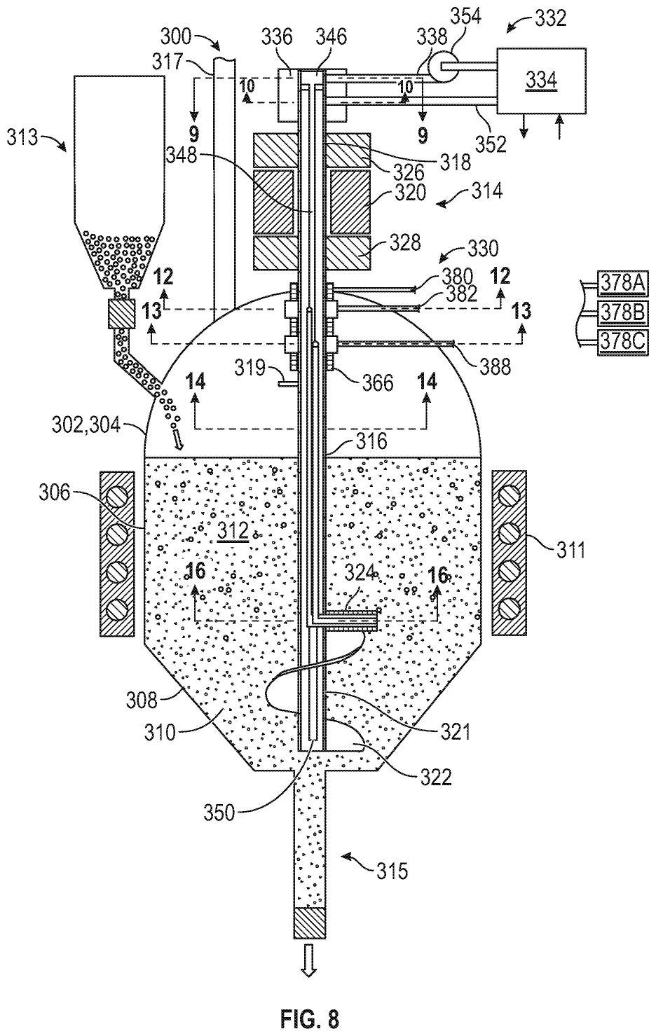

FIG. 8 illustrates another embodiment of a reactor system 300 comprising a reactor vessel 302 configured similarly to the vessel 12 of FIG. 1, and comprising a first portion 304, a second portion 306, and a tapered third or lower portion 308. A plurality of granules or particles 310 are shown forming a bed 312 in the vessel 302. An actuator assembly 314 comprising a shaft 316 is shown positioned at least partially within the reactor vessel 302 with a first end portion 318 coupled to a motor 320, and a second end portion 321 comprising actuator elements 322 and 324 disposed within the particle bed 312. In the illustrated embodiment, the actuator elements 322 and 324 are configured similarly to the blade members 28 and 34 of FIG. 1 above, although the shaft may comprise any of the actuator elements described herein alone or in any combination. Bearings 326 and 328 positioned above and below the motor 320, respectively, can support and stabilize the shaft 316.

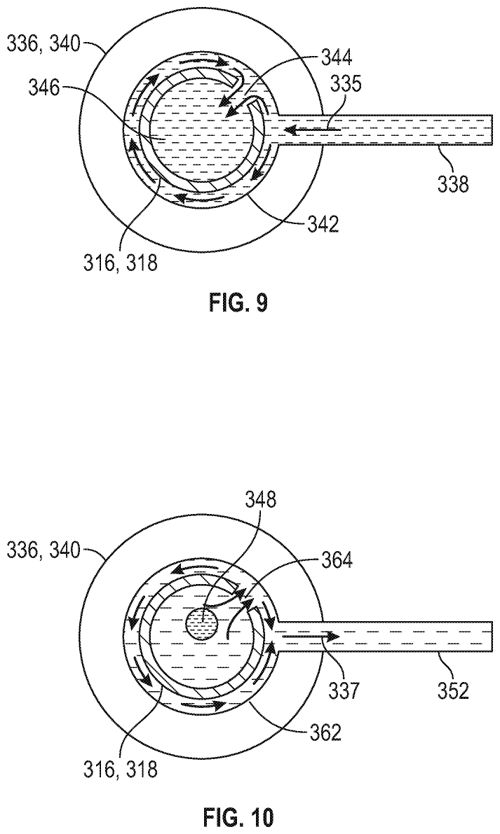

The reactor system 300 can comprise a gas injection system generally indicated at 330, and a cooling or thermal management system generally indicated at 332. Each of the gas injection system 330 and the thermal management system 332 can comprise one or more conduits and/or fluid circuits for delivering a variety of liquids and/or gases to the interior of the shaft 316. For example, the thermal management system 332 can comprise a coolant source configured as a heat exchanger 334, and a rotary union or rotary valve 336 coupled to the first end portion 318 of the shaft 316. A conduit 338 can fluidly couple the heat exchanger 334 with the rotary union 336. FIGS. 9 and 10 illustrate the rotary union 336 in greater detail. The rotary union 336 can comprise an external body or housing 340 in which the shaft 316 is received. The housing 340 can define a chamber or injection plenum 342 around the exterior of the shaft 316 that is in fluid communication with the conduit 338. An opening 344 defined in the shaft 316 can provide a passage between the injection plenum 342 and an interior chamber or plenum 346 at the first end portion 318 of the shaft. In certain embodiments, the housing 340 can include O-rings or other seals disposed above and/or below the injection plenum.

Referring again to FIG. 8, a conduit 348 can extend from the plenum 346 internally of the shaft from the first end portion 318 to the second end portion 321. Coolant fluid delivered from the heat exchanger 334 to the plenum 346 via the conduit 338 and the rotary union 336 can thus flow along the length of the shaft within the internal conduit 348 (see flow lines 335 in FIG. 9). The conduit 348 can comprise an outlet 350 at its opposite end (e.g., at the second end portion 321 of the shaft 316) such that coolant can exit the conduit 348 and flow back up the shaft in contact with the interior walls of the shaft, and in contact (e.g., flowing around) the conduits of the gas injection system 332. Referring to FIGS. 8 and 10, coolant can be withdrawn from the first end portion 318 of the shaft 316 via a conduit 352 and returned to the heat exchanger 334 for cooling, before being reintroduced into the shaft. For example, with reference to FIG. 10, the rotary union 336 can define a second or withdrawal plenum 362, which can be in fluid communication with the interior of the shaft 316 via an opening 364. Fluid exiting the shaft 316 into the plenum 362 can be conducted through the conduit 352 to the heat exchanger 334, as indicated by flow arrows 337. In certain embodiments, a pump 354 in line with the conduit 338 can circulate coolant through the thermal management system 332. In some embodiments, cooling gas can be vented from the shaft into the reactor vessel through a vent port 319 in communication with the interior of the shaft 316 (FIG. 8).

In certain embodiments, the coolant can be a liquid such as water, a water-alcohol solution, heat transfer oils such as paraffinic oils, liquid metals, such as low melting temperature liquid metals like mercury and/or gallium, etc. In other embodiments, the coolant can be a gas such as hydrogen, an inert gas such as nitrogen, argon, helium, etc., or mixtures thereof.

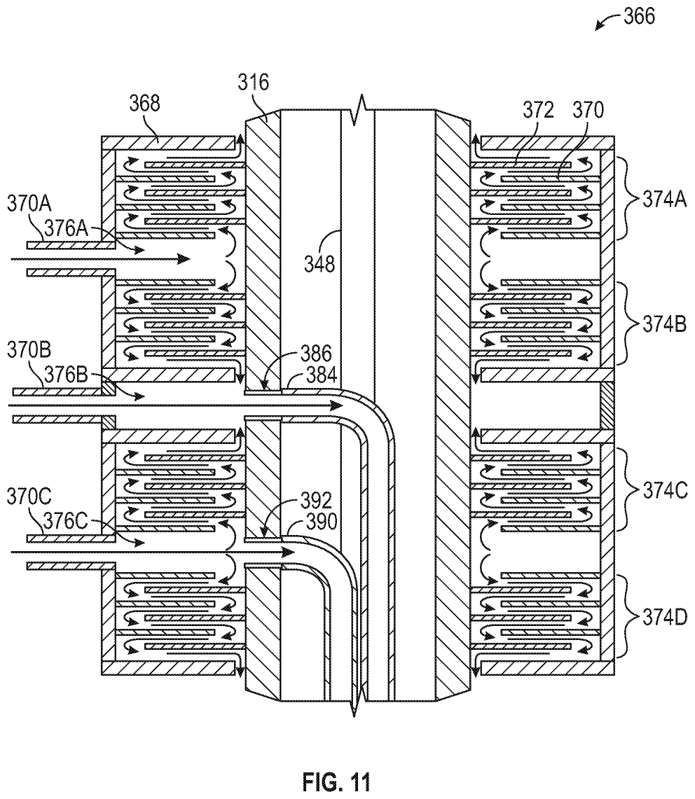

Returning to FIG. 8, the gas injection system 330 can comprise a non-contact sealing assembly 366 disposed around the shaft 316 where the shaft extends into the reactor vessel 302, similar to the configurations described above. FIGS. 11, 12, and 13 illustrate the sealing assembly 366 in greater detail. The sealing assembly 366 can comprise a housing 368 including a plurality of inlet fittings 370A-370C. The sealing assembly 366 can comprise a plurality of labyrinth seals 374A-374D comprising groups of baffle members 370 of the housing overlapping with baffle members 372 extending radially outwardly from the shaft 316. The labyrinth seals 374A-374D can be spaced apart from each other along the shaft 316, and can define plenums 376A-376C surrounding the shaft at the location of the corresponding inlet fittings 370A-370C, similar to the embodiment of FIG. 4.

Referring to FIGS. 8 and 11, the plenum 376A can be configured as a gland seal inlet plenum. Sealing gas (e.g., hydrogen) can be supplied to the plenum 376A from a sealing gas source 378A (FIG. 8) via a conduit 380 in communication with the inlet fitting 370A. The sealing gas can be at a pressure greater than ambient pressure such that a portion of the gas introduced into the plenum 376A can flow through the labyrinth seal 374A and into the external environment to isolate the interior of the housing 368 from the environment. A portion of the gas can also flow through the labyrinth seal 374B and into the plenum 376B.

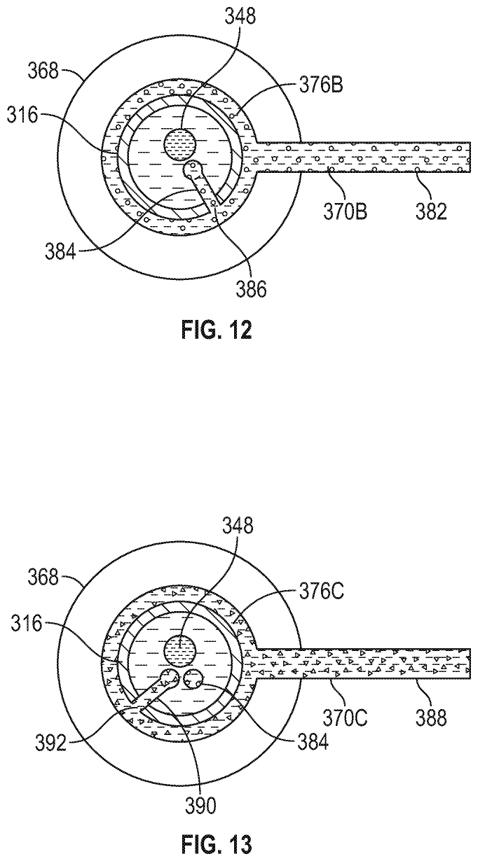

Referring to FIGS. 8 and 12, the plenum 376B can be configured as a secondary or shielding gas inlet plenum. A shielding gas (e.g., hydrogen or other inert gas(es), without reactive species) can be supplied to the plenum 376B from a shielding gas source 378B (FIG. 8) via a conduit 382 in communication with the inlet fitting 370B. A conduit 384 located internally of the shaft 316 can be in fluid communication with the plenum 376B via an opening 386 in the shaft. The conduit 384 can extend to the second end portion 321 of the shaft, and can be in fluid communication with the blade member 324, as further described below. In other embodiments, the plenum 376B and the inlet fitting 370B can be configured to conduct sealing gas and shielding gas, and the inlet 370A and the plenum 376A can be removed.

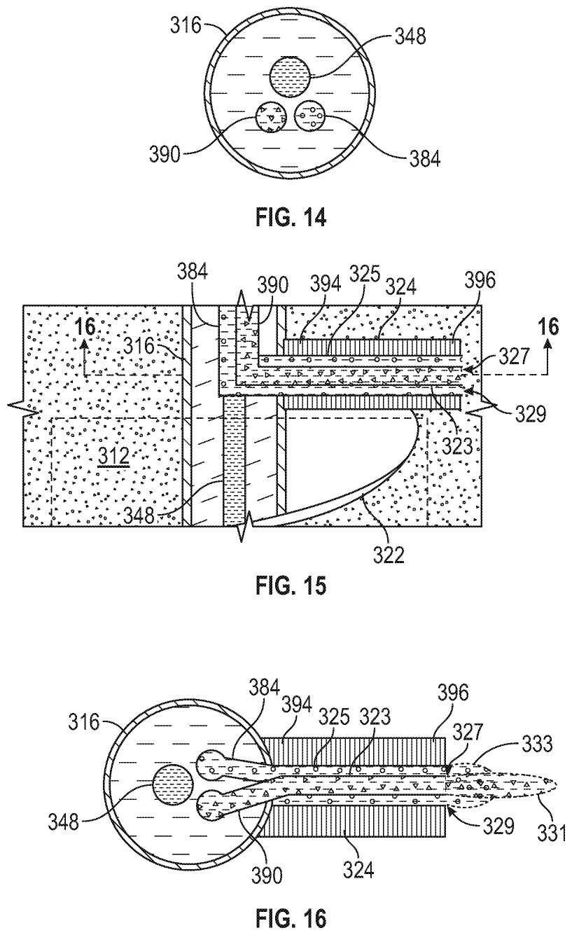

Referring to FIGS. 8 and 13, the plenum 376C can be configured as a precursor gas inlet plenum. A precursor gas (e.g., silane) can be supplied to the plenum 376C from a precursor gas source 378C via a conduit 388 in fluid communication with the inlet fitting 370C. A conduit 390 located internally of the shaft 316 can be in fluid communication with the plenum 376C via an opening 392 in the shaft. The conduit 390 can extend along the length of the shaft and can also be in fluid communication with the blade member 324, as further described below. FIG. 14 illustrates a cross-sectional view through the shaft 316 taken below the sealing assembly 366 and looking upwardly toward the first portion 318, and illustrating the coolant conduit 348, the shielding gas conduit 384, and the precursor gas conduit 390.

Referring to FIGS. 15 and 16, and as noted above, the shielding gas conduit 384 and the precursor gas conduit 390 can be in fluid communication with blade member 324. With reference to FIG. 16, the blade member 324 can be configured as a nozzle or introducer, and can include a first end portion 394 coupled to the shaft 316 and a second end portion 396. The blade member 324 can define an inner conduit 323 and a coaxial outer conduit 325 extending along its length. The inner and outer conduits 323 and 325 can comprise respective outlets 327 and 329 at the second end portion 396. The outlets 327 and 329 can be in fluid communication with the reactor vessel 302, and can collectively form a coaxial nozzle. The precursor gas conduit 390 can be coupled to the inner conduit 323 at or near the first end portion 394 of the blade 324 (e.g., within the shaft 316), and the shield gas conduit 384 can be coupled to the outer conduit 325.

The reactor system 300 can also comprise heat sources 311, a particle source 313, a particle withdrawal system 315, and a recycle conduit 317, similar to the configuration of FIG. 1.

In operation, the reactor vessel 302 can be filled with particles 310, the heat sources 311 can be activated to pre-heat the particles, and the shaft 316 can be rotated to circulate the particle bed around the reactor vessel 302. In some embodiments, circulation of the particles 310 can be in a toroidal path similar to that shown in FIG. 5. Sealing gas can be supplied to the plenum 376A from the sealing gas source 378A, shielding gas can be supplied to the plenum 376B from the shielding gas source 378B, and precursor gas can be supplied to the plenum 376C from the precursor gas source 378C. At least the sealing gas can be at a pressure greater than the ambient pressure such that a portion of the sealing gas flows through the labyrinth seal 374A and exits the housing 368 to seal the housing from the ambient. The remainder of the sealing gas can flow through the labyrinth seal 374B into the plenum 376B, where it can mix with precursor gas supplied from the precursor gas source 378C.

Shielding gas can enter the shielding gas conduit 384 via the plenum 376B, and can be conducted along the length of the shaft 316 to the outer conduit 325 of the blade member 324. Precursor gas can enter the precursor gas conduit 390 via the plenum 376C, and can be conducted along the length of the shaft 316 to the inner conduit 323 of the blade member 324. Referring to FIG. 16, precursor gas can exit the inner conduit 323 through the outlet 327 to form a stream, cone, or plume 331. Shielding gas can exit the outer conduit 325 through the coaxial outlet 329 such that the shielding gas forms an envelope or secondary plume 333 surrounding the precursor gas plume 331. The envelope 333 can extend from the outlet 329 along at least a portion of the length of the precursor gas plume 331. In certain embodiments, the shielding gas envelope 333 can thermally insulate the precursor gas within the envelope, reducing pyrolization or decomposition of the precursor gas adjacent the blade member 324 and the outlets 327, 329. This can reduce fouling of the outlets due to buildup of material deposited by pyrolization of the precursor gas. The shielding gas envelope can also provide a layer of gas that has no reactive species. The shape and dimensions of the shielding gas envelope 333 can be controlled by, for example, the size and shape of the outlet 329, the pressure of the shielding gas, and/or the flow rate of the shielding gas.

In examples in which the precursor gas is silane, once the silane gas reaches the pyrolization temperature, the gas can thermally decompose and deposit silicon on the seed particles 310 (FIG. 8). In certain embodiments, pyrolization can occur in a reaction plume within the bed 312 similar to the plume 76 of FIG. 5. Particles can be selectively added and removed from the reactor vessel 302 as the process continues. Coolant supplied along the conduit 348 can cool the shaft 316 and the blade members 322 and 324, reducing or preventing material deposition on these components.

The reactor systems described herein can provide any of a number of significant advantages over known granule production systems. For example, the systems described herein can achieve higher energy efficiency compared to other systems such as fluidized bed reactors. Higher energy efficiency can be achieved by eliminating the need for bed fluidization gas, which must be compressed and heated prior to introduction to the reactor vessel to elutriate the bed and maintain the selected bed temperature. Certain embodiments of the reactor systems described herein can also allow production of material-coated particles by stirring the particle bed and injecting the precursor gas with the actuator assembly, without the need for cumbersome support systems such as the fluidization gas compression and gas heating equipment commonly associated with fluidized bed reactors. Certain embodiments of the disclosed reactors can produce equivalent or higher volumes of product than a typical fluidized bed reactor in a smaller facility, which can provide significant capital, operational, and maintenance cost savings. Certain embodiments of the disclosed reactor systems can offer higher yields of granular product (e.g., granular silicon) with less precursor gas flowing through the bed, and less net powder and fine particulate production as compared to typical fluidized bed reactors. Additionally, by covering precursor gas-wetted surfaces of the reactor system with silicon or silicon carbide, it is possible to achieve a higher product quality or purity compared to reactors made from other metals. Certain embodiments of the reactor systems described herein can also be used for the production of hybrid materials, such as silicon-coated carbon particles for use in lithium-ion battery anode materials, coated granules in food, pharmaceuticals, and/or nuclear power applications (e.g., coating uranium, plutonium, and/or other nuclear fuel pellets with (burnable) neutron absorber materials), and/or coating silicon carbide granules with magnesium diboride.

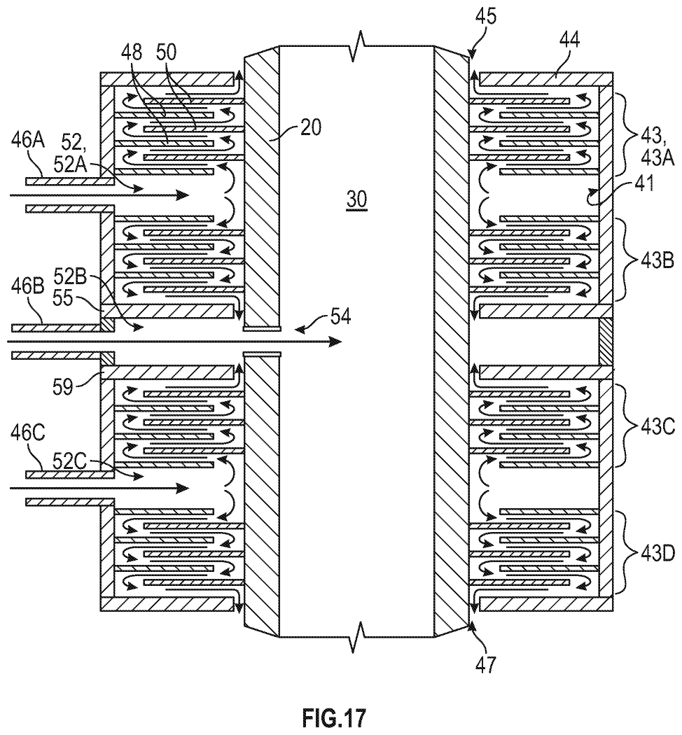

In other embodiments, the shaft 20 can be configured as a hollow tube, but need not comprise internal conduits. Precursor gas, cooling gas, and/or sealing gas can be mixed in one or more plenums of the non-contact sealing assembly and injected into the interior of the shaft, and out of the blade member 34 into the particle bed. FIG. 17 illustrates a representative embodiment of the non-contact sealing assembly 42 configured for use in such a system. The shaft 20 can comprise an opening 54 in fluid communication with the plenum 52B and with the interior “conduit” 30 of the shaft. Precursor gas supplied to the plenum 52B can be injected into the shaft 20 through the opening 54, mixed with sealing gas entering the plenum 52B from the labyrinth seal 43B and the labyrinth seal 43C.

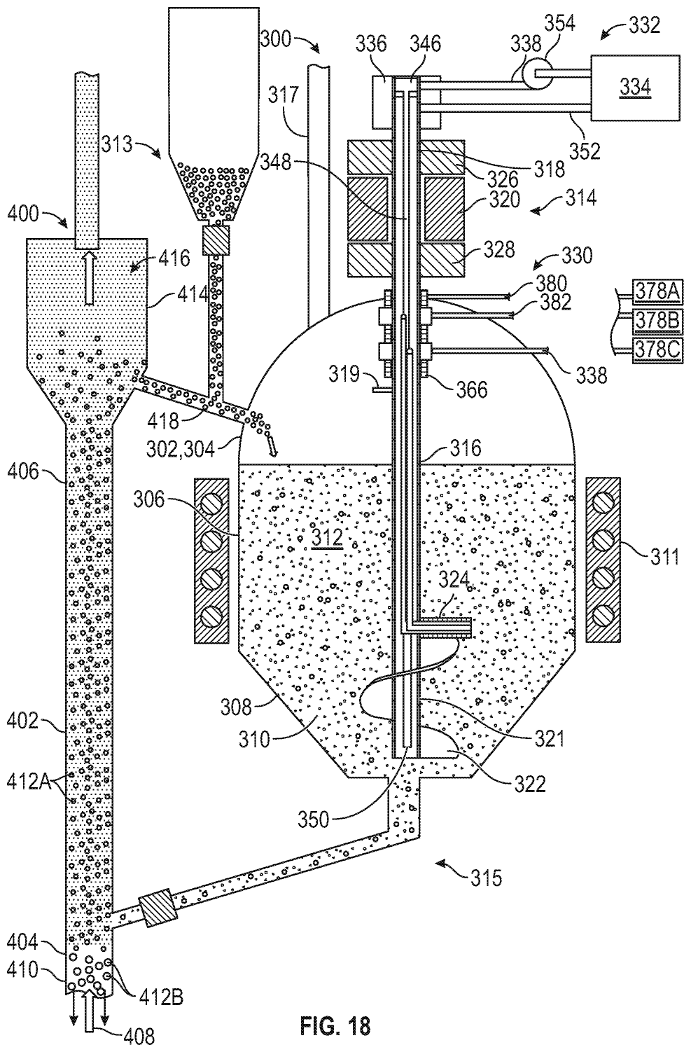

FIG. 18 illustrates another embodiment of the reactor system 300 including a particle separator or classifier system 400 coupled to the particle withdrawal system 315. The particle classifier system 400 can include a main conduit 402 including a first end portion 404 and a second end portion 406. Particles discharged from the reactor vessel 302 can enter the main conduit 402 through a port in the first end portion 404. An upwardly directed gas flow (e.g., hydrogen or another inert gas) represented by arrow 408 can enter the conduit through an inlet 410 at the first end portion 404. The gas flow 408 can be controlled to elutriate particles below a first threshold size or mass. For example, particles 412A having a size or mass below the first threshold can be elutriated or fluidized, and conveyed upwardly through the conduit 402 by the gas flow. Particles 412B having a size or mass above the first threshold can fall through the gas inlet 410, and can be directed away for further processing (e.g., degasification and product packaging). At a chamber or plenum 414 coupled to the second end portion 406 of the conduit, dust particles 416 having a size or mass below a second threshold can be separated from the particles 412A. The dust particles 416 can be conveyed away by the gas stream for filtration and recycling, while the particles 412A can be returned to the reactor vessel 302 through a conduit 418. Such a particle classifier system can be incorporated into any of the reactor system embodiments described herein.

### Example 1

Table 1 below provides simulated performance metrics for a representative example of the stirred bed reactor system 10 in which the inner diameter of the reactor vessel 12 is 91.4 cm (36 in) compared to a fluidized bed reactor in which the inner diameter of the reactor vessel is 67.6 cm. Performance metrics for the stirred bed reactor are given for particles with a mean particle diameter (dₛᵥ) of 1.0 mm, 1.5 mm, and 2.0 mm. The mean particle diameter of particles in the fluidized bed reactor is 1.0 mm. Other parameters given include the silane gas (SiH₄) flow as a percentage of nominal silane gas flow in the fluidized bed reactor, in pounds per hour, and moles per hour. Bed temperature and bed pressure figures are given, along with primary hydrogen gas (H₂) flow in pounds per hour and moles per hour for each reactor type and particle size. The ratio of silane and hydrogen gas is also given, along with secondary hydrogen gas flow, fluidization gas flow (hydrogen), the gas velocity U in the reactor, and the minimum fluidization velocity (U_{mf}) for each particle size. As shown in Table 1, in the fluidized bed reactor with particles having a mean particle diameter of 1.0 mm, the gas velocity U is 95 cm/s and the minimum fluidization velocity for such particles is 63.7 cm/s. Thus, the seed particles in the bed of the fluidized bed reactor are elutriated.

TABLE 1
Performance of Stirred Bed Reactor with
Reactor Vessel having 91.4 cm Diameter

| | | 91.4 cm SBR Liner Dia. | | |
|---|---|---|---|---|
| | FBR | SBR | SBR | SBR |
| Reactor ID (cm) | 67.6 | 91.4 | 91.4 | 91.4 |
| % SiH₄ nominal FBR | 100.0% | 200.0% | 200.0% | 200.0% |
| SiH₄ Flow (lb/hr) | 290 | 580 | 580 | 580 |
| SiH₄ Flow (mol/hr) | 4095 | 8191 | 8191 | 8191 |
| dₛᵥ (mm) | 1.0 | 1.0 | 1.5 | 2.0 |
| Bed Temperature (F.) | 1400 | 1400 | 1400 | 1400 |
| Bed Pressure (psig) | 5.0 | 5.0 | 5.0 | 5.0 |
| Primary H₂ (lb/hr) | 15.1 | 30.2 | 30.2 | 30.2 |
| Primary H₂ (mol/hr) | 3391 | 6782 | 6782 | 6782 |
| Primary SiH₄:H₂ | 1.2 | 1.2 | 1.2 | 1.2 |
| Secondary H₂ (lb/hr) | 13.0 | 0.0 | 0.0 | 0.0 |
| Fluidization H₂ (lb/hr) | 21.8 | 0.0 | 0.0 | 0.0 |
| U (cm/s) | 95.0 | 62.0 | 62.0 | 62.0 |
| U_{mf} (cm/s) | 63.7 | 63.7 | 138.7 | 233.2 |

In contrast, in the stirred bed reactor, silane gas flow equal to 200% of the silane gas flow in the fluidized bed reactor can be introduced, and the overall gas velocity U in the stirred bed reactor can be 62 cm/s. Thus, two times the mass flow of silane gas of a fluidized bed reactor can be introduced into the stirred bed reactor at a lower velocity than in the fluidized bed reactor. As a result, the particles are not elutriated, and the silane gas moves more slowly through the particle bed, increasing the time available for pyrolization and increasing yield, and reducing attrition due to, for example, jet milling action of fluidization nozzles in a fluidized bed reactor. Similar parameters are shown for 1.5 mm and 2.0 mm particles in the stirred bed reactor, where minimum fluidization velocities are correspondingly greater.

### Example 2

Similar values are given in Table 2 for another example of a stirred bed reactor in which the reactor vessel 12 has an inner diameter of 45.7 cm (18 in). Data of gas velocity U in the reactor and minimum fluidization velocity U_{mf} are given for particle sizes of 1.0 mm, 1.5 mm, and 2.0 mm, and for silane gas flow equal to 100% of nominal silane gas flow in a fluidized bed reactor having a diameter of 67.6 cm and 1.0 mm particles. Data are also given for silane gas flow equal to 75.9% of nominal silane gas flow in such a fluidized bed reactor. For a stirred bed reactor vessel 45.7 cm in diameter with particles having a mean particle diameter of 1.0 mm, silane gas flow less than 3107 mol/hour, or 75.9% of the silane gas flow in the fluidized bed reactor, may be required to avoid fluidization. However, fluidization can be avoided with particles having a mean particle diameter of 1.5 mm or greater with silane gas flow up to 4,095 mol/hour (100% of nominal flow in the fluidized bed reactor), or more.

TABLE 2
Performance of Stirred Bed Reactor with Reactor Vessel having 45.7 cm Diameter

| | | 45.7 cm SBR (4,095 mol/hr SiH₄) | | | 45.7 cm SBR (3,107 mol/hr SiH₄) | | |
|---|---|---|---|---|---|---|---|
| | FBR | SBR | SBR | SBR | SBR | SBR | SBR |
| Reactor ID (cm) | 67.6 | 45.7 | 45.7 | 45.7 | 45.7 | 45.7 | 45.7 |
| % SiH₄ nominal FBR | 100.0% | 100.0% | 100.0% | 100.0% | 75.9% | 75.9% | 75.9% |
| SiH₄ Flow (lb/hr) | 290 | 290 | 290 | 290 | 220 | 220 | 220 |
| SiH₄ Flow (mol/hr) | 4095 | 4095 | 4095 | 4095 | 3107 | 3107 | 3107 |
| dₛᵥ (mm) | 1.0 | 1.0 | 1.5 | 2.0 | 1.0 | 1.5 | 2.0 |
| Bed Temperature (F.) | 1400 | 1400 | 1400 | 1400 | 1400 | 1400 | 1400 |
| Bed Pressure (psig) | 5.0 | 5.0 | 5.0 | 5.0 | 5.0 | 5.0 | 5.0 |
| Primary H₂ (lb/hr) | 15.1 | 15.1 | 15.1 | 15.1 | 11.5 | 11.5 | 11.5 |
| Primary H₂ (mol/hr) | 3391 | 3391 | 3391 | 3391 | 2582 | 2582 | 2582 |
| Primary SiH₄:H₂ | 1.2 | 1.2 | 1.2 | 1.2 | 1.2 | 1.2 | 1.2 |
| Secondary H₂ (lb/hr) | 13.0 | 0.0 | 0.0 | 0.0 | 0.0 | 0.0 | 0.0 |
| Fluidization H₂ (lb/hr) | 21.8 | 0.0 | 0.0 | 0.0 | 0.0 | 0.0 | 0.0 |
| U (cm/s) | 95.0 | 123.8 | 123.8 | 123.8 | 94.0 | 94.0 | 94.0 |
| U_{mf} (cm/s) | 63.7 | 63.7 | 138.7 | 233.2 | 63.7 | 138.7 | 233.2 |

### Example 3

In a representative example, a reactor system similar to the reactor system 10 can comprise a gas tight chamber having a selected pressure rating and configured as a stirred bed reactor (SBR). A bed of granular silicon or other type of granules, depending on the application, can reside within the chamber. Silicon wetted surfaces can be lined or coated with silicon, silicon carbide, or quartz. Located outside the reactor vessel along the sides of the bed is a heater. The heater can be located just outside the gas tight chamber and can be inductive, electrically resistive, etc. A rotary shaft with an impeller assembly can be suspended within the bed. The shaft can be supported from one or more bearing assemblies, and can be coupled to a rotary drive motor. The shaft can have a coaxial gas tube that supplies both cooling gas (e.g., H₂, helium, argon, etc., which may initially be in a liquid or gaseous state) and silane that flows through the trailing edge of the helical impeller or the outer diameter edge of the Wave Motion Blade. An external liquid cooled system can be used in place of, or in addition to, the gas cooling system to prevent depositing silicon on the impeller shaft or impeller. To provide a gas-tight, non-contaminating seal at the penetration through the chamber wall and through the manifolds that couple the rotating shaft with coaxial tube to the fixed cooling H₂ and silane supply lines, labyrinth seals that are pressurized with H₂ are provided. The reactor bottom can be conically shaped to help provide mass flow circulation to the bottom of the impeller to provide an overall circulating bed. A discharge tube can include a flow control device such as a metering valve to allow either continuous or batch discharges from the reactor. In an alternative arrangement, a gas classifier can be included to separate larger particles from smaller ones and recycle the smaller ones to the Bed/Seed Charge Feed system (FIG. 18). The hydrogen produced from the pyrolysis of silane and gland seal leakage into the SBR chamber can be directed to a filter system after flowing through an external cooler and compressor, and can be recycled back to the classifier/cooling/gland sealing supply or to a silane production unit. A seed particle feed line can be connected to the upper section of the SBR (either through the classifier recycle line or an independent line).

In operation, the impeller shaft can start rotation, and the chamber can be purged of oxygen with N₂ or another inert gas supplied to the gland seal, cooling, and silane lines. Once purged, the gas can be changed to establish a H₂ atmosphere. The initial bed of granular material can be charged via the seed supply line and the heaters can be turned on to heat the bed to a selected temperature.

In certain embodiments, a silicon carbide-lined reactor can be used, for example, for product purity purposes. This can prevent granules from contacting hot, contaminating (non-silicon) metal. In certain embodiments, prior to introducing the granule bed, silane gas can be injected into a heated reactor to provide a layer of silicon deposited on the reactor walls by chemical vapor deposition (CVD).

The shaft/impeller assembly can be rotated to produce an upward flow of granular material at the center of the chamber with a downward flow of granular material along the chamber walls. There can also be swirling motion of the bed (e.g., looking downward). When the selected reaction temperature is reached inside the chamber, a silane gas flow can be established to begin the production process. The forces provided by the impeller blades can establish an activated flow region with the highest relative particle velocity occurring around the impeller blades. The flow rate and/or concentration of silane injected from the blade tips (or trailing edges) can be adjusted to confine the pyrolysis reaction zone within the active motion regions within the bed. Any of the following measures can be used either independently, or in any combination, to either increase the active motion area or decrease the extent of the silane reactive plume: (1) increase the rpm, pitch, or diameter of the impeller; (2) increase the bed temperature; or (3) decrease the flow or concentration of silane injected into the bed. These measures can reduce or prevent heterogeneous decomposition (e.g., CVD), which can cause relatively static granules to fuse together and form agglomerates that can limit the operational run time of the reactor by interfering with impeller motion, block the bottom discharge, or increase the thermal resistance from the heaters to the bed. The impeller shaft's speed may also be periodically increased or pulsed to mix farther out in the bed while normally operating at a lower speed.

To maintain a sufficient number of particles within the bed, a seed feed system's flow control device can provide a continuous or intermittent flow of particles into the chamber. The bed level can be determined by monitoring the impeller shaft torque, and/or through one or more temperature or vibration probe(s) located near the desired bed height. A guided wave radar system can also be used to monitor the bed height. Bed level control can be established by adjusting the particle withdrawal rate, classifier gas flow, and/or seed particle flow.

In certain embodiments, an additional mode of operation can be established following the granular production by stopping the flow of silane and heating the SBR chamber to a higher temperature with hydrogen, or alternatively changing to an argon atmosphere, to anneal the granular silicon.

### Explanation of Terms

For purposes of this description, certain aspects, advantages, and novel features of the embodiments of this disclosure are described herein. The disclosed methods, apparatus, and systems should not be construed as being limiting in any way. Instead, the present disclosure is directed toward all novel and nonobvious features and aspects of the various disclosed embodiments, alone and in various combinations and sub-combinations with one another. The methods, apparatus, and systems are not limited to any specific aspect or feature or combination thereof, nor do the disclosed embodiments require that any one or more specific advantages be present or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

As used in this disclosure and in the claims, the singular forms “a,” “an,” and “the” include the plural forms unless the context clearly dictates otherwise. Additionally, the term “includes” means “comprises.” Further, the terms “coupled” and “associated” generally mean electrically, electromagnetically, and/or physically (e.g., mechanically or chemically) coupled or linked and does not exclude the presence of intermediate elements between the coupled or associated items absent specific contrary language.

In some examples, values, procedures, or apparatus may be referred to as “lowest,” “best,” “minimum,” or the like. It will be appreciated that such descriptions are intended to indicate that a selection among many alternatives can be made, and such selections need not be better, smaller, or otherwise preferable to other selections.

In the description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Unless otherwise indicated, all numbers expressing quantities of components, forces, moments, molecular weights, percentages, temperatures, times, and so forth, as used in the specification or claims are to be understood as being modified by the term “about.” Accordingly, unless otherwise indicated, implicitly or explicitly, the numerical parameters set forth are approximations that can depend on the desired properties sought and/or limits of detection under test conditions/methods familiar to those of ordinary skill in the art. When directly and explicitly distinguishing embodiments from discussed prior art, the embodiment numbers are not approximates unless the word “about” is recited. Furthermore, not all alternatives recited herein are equivalents.

Although there are alternatives for various components, parameters, operating conditions, etc., set forth herein, that does not mean that those alternatives are necessarily equivalent and/or perform equally well. Nor does it mean that the alternatives are listed in a preferred order unless stated otherwise.

In view of the many possible embodiments to which the principles of the disclosed technology may be applied, it should be recognized that the illustrated embodiments are only preferred examples and should not be taken as limiting the scope of the disclosure. Rather, the scope of the disclosure is at least as broad as the following claims. We therefore claim all that comes within the scope and spirit of these claims.

1. An apparatus, comprising:
a reactor vessel;
an actuator assembly comprising a shaft disposed at least partially within the reactor vessel, and an actuator element coupled to the shaft and rotatable therewith; and
a precursor gas supply in fluid communication with the actuator assembly;
wherein the actuator assembly is configured to circulate seed particles of a seed particle bed in the reactor vessel with the actuator element, and to introduce precursor gas from the gas supply to the seed particle bed, when seed particles are received in the reactor vessel.

2. The apparatus of claim 1, the actuator element comprises a blade member extending helically around the shaft.

3. The apparatus of claim 1, wherein:
the actuator element is a first actuator element;
the actuator assembly further comprises a second actuator element coupled to the shaft; and
the second actuator element comprises an outlet in fluid communication with the precursor gas supply.

4. The apparatus of claim 3, wherein:
the assembly further comprises a non-contact sealing assembly comprising a housing coupled to the reactor vessel and disposed around the shaft to seal an interior of the reactor vessel from the exterior environment; and
the precursor gas supply is in fluid communication with the housing of the non-contact sealing assembly.

5. The apparatus of claim 4, wherein the shaft comprises an internal conduit in fluid communication with the second actuator element and with the housing of the non-contact sealing assembly, and the internal conduit is configured to conduct precursor gas from the housing to the second actuator element.

6. The apparatus of claim 5, wherein the non-contact sealing assembly comprises a first labyrinth seal and a second labyrinth seal spaced apart from each other along the shaft within the housing, the first and second labyrinth seals defining a plenum therebetween.

7. The apparatus of claim 6, wherein the plenum is in fluid communication with the internal conduit of the shaft via an opening in the shaft such that precursor gas can flow from the plenum into the internal conduit of the shaft.

8. The apparatus of claim 6, wherein:
the plenum is a first plenum;
the internal conduit is a first internal conduit; and
the housing further comprises a second plenum in fluid communication with a second internal conduit of the shaft, and with a shield gas source.

9. The apparatus of claim 8, wherein:
the second actuator element comprises an inner conduit and an outer conduit, the outer conduit being coaxially disposed around the inner conduit;
the first internal conduit of the shaft is in fluid communication with the inner conduit of the second actuator element; and
the second internal conduit of the shaft is in fluid communication with the outer conduit of the second actuator element such that when precursor gas is supplied to the inner conduit and shield gas is supplied to the outer conduit, the shield gas forms a gas envelope around precursor gas exiting the outlet of the second actuator element.

10. The apparatus of claim 3, wherein:
the shaft comprises a first end portion coupled to a driver and a second end portion disposed within the reactor vessel;
the first actuator element is coupled to the second end portion of the shaft; and
the second actuator element is offset from the first actuator element along the shaft toward the first end portion of the shaft.

11. The apparatus of claim 1, wherein the shaft further comprises a coolant conduit in fluid communication with a coolant source.

12. The apparatus of claim 11, wherein:
the shaft is configured as a hollow tube comprising a lumen;
the coolant conduit comprises an outlet within the lumen of the shaft; and
the assembly further comprises a rotary union coupled to the shaft and in fluid communication with the coolant conduit and with the lumen such that coolant can be introduced to the coolant conduit and withdrawn from the lumen of the shaft.

13. A method of using the apparatus of claim 1, the method comprising:
circulating a plurality of seed particles contained in the reactor vessel with the actuator assembly; and
with the actuator assembly, introducing a precursor gas comprising a first material into the reactor vessel such that the precursor gas flows through the plurality of seed particles;
decomposing the precursor gas such that the first material is deposited on the seed particles to provide product particles; and
withdrawing the product particles from the reactor vessel.

14. A method, comprising:
circulating a plurality of seed particles contained in a reactor vessel with an actuator assembly comprising a shaft and an actuator element coupled to the shaft;
with the actuator assembly, introducing a precursor gas comprising a first material into the reactor vessel such that the precursor gas flows through the plurality of seed particles;
decomposing the precursor gas such that the first material is deposited on the seed particles to form product particles; and
withdrawing the product particles from the reactor vessel.

15. The method of claim 14, wherein introducing the precursor gas further comprises introducing the precursor gas with the actuator element of the actuator assembly.

16. The method of claim 14, wherein circulating the seed particles further comprises circulating the seed particles along a path that extends away from the actuator element in a direction along the shaft, radially outwardly away from the shaft, and along walls of the reactor vessel.

17. The method of claim 14, wherein decomposing the precursor gas further comprises pyrolyzing the precursor gas by application of heat from heat sources external to the reactor vessel.

18. The method of claim 14, wherein introducing the precursor gas further comprises supplying the precursor gas to the actuator assembly through a non-contact sealing assembly disposed around the shaft.

19. The method of claim 14, further comprising:
supplying a coolant to the actuator assembly; and
withdrawing the coolant from the shaft.

20. The method of claim 14, wherein circulating the plurality of seed particles further comprises rotating the shaft such that the actuator assembly lifts seed particles to generate a rotating wave in the seed particle bed.

21. An apparatus, comprising:
a reactor vessel;
actuator means disposed at least partially within the reactor vessel, the actuator means comprising torque-transmission means and stirring means coupled to the torque-transmission means; and
a precursor gas supply in fluid communication with the actuator means;
wherein the actuator means is configured to stir seed particles of a seed particle bed in the reactor vessel with the stirring means, and to introduce precursor gas from the gas supply to the seed particle bed, when seed particles are received in the reactor vessel.
